(19) United States
(12) Patent Application Publication
(10) Pub. No.: US 2019/0267540 A1
(43) Pub. Date: Aug. 29, 2019

(54) SPIN CURRENT MAGNETIZED ROTATION ELEMENT, MAGNETORESISTANCE EFFECT ELEMENT AND MAGNETIC MEMORY

(71) Applicant: TDK CORPORATION, Tokyo (JP)

(72) Inventor: Yohei SHIOKAWA, Tokyo (JP)

(73) Assignee: TDK CORPORATION, Tokyo (JP)

(21) Appl. No.: 15/965,053

(22) Filed: Apr. 27, 2018

(30) Foreign Application Priority Data
Feb. 27, 2018 (JP) 2018-033102

(51) Int. Cl. H01L 43/10; H01L 43/08; H01L 27/22; H01L 43/04; H01F 10/32; G11C 11/16; G11C 11/18

(52) U.S. Cl. CPC H01L 43/10; H01L 43/08; H01L 27/226; G11C 11/18; H01F 10/329; H01F 10/3259; G11C 11/161; H01L 43/04

(57) ABSTRACT

A spin current magnetized rotation element includes: a first ferromagnetic layer configured for a magnetization direction to be changed; and a spin-orbit torque wiring layer that extends in a second direction intersecting a first direction which is a direction orthogonal to a plane of the first ferromagnetic layer and is positioned in the first direction from the first ferromagnetic layer, wherein the spin-orbit torque wiring layer includes a superparamagnetic body therein, and the superparamagnetic body contains any one of a magnetic element selected from a group consisting of Fe, Co, Ni, and Gd.

Priority is claimed on Japanese Patent Application No. 2018-033102, filed on Feb. 27, 2018, the content of which is incorporated herein by reference.

### BACKGROUND OF THE INVENTION

### Field of the Invention

The present disclosure relates to a spin current magnetized rotation element, a magnetoresistance effect element, and a magnetic memory.

### Description of Related Art

A giant magnetoresistance (GMR) element made of a multi-layer film including a ferromagnetic layer and a non-magnetic layer and a tunnel magnetoresistance effect (TMR) element using an insulating layer (tunnel barrier layer, barrier layer) as a non-magnetic layer are known. In general, a TMR element has a higher element resistance than a GMR element, but a magnetoresistance (MR) ratio of a TMR element is higher than an MR ratio of a GMR element. Therefore, as an element for a magnetic sensor, a high-frequency component, a magnetic head, and a nonvolatile random access memory (MRAM), a TMR element is being focused upon.

A TMR element includes two ferromagnetic layers and an insulating layer interposed between the ferromagnetic layers. When the directions of magnetization of the two ferromagnetic layers change, the element resistance of a TMR element changes. An MRAM reads and writes data using the characteristics of a TMR element. As a writing method of an MRAM, a method in which writing (magnetization rotation) is performed using a magnetic field created by a current and a method in which writing (magnetization rotation) is performed using a spin transfer torque (STT) generated when a current flows in a lamination direction of a magnetoresistance effect element are known.

While magnetization rotation of a TMR element using an STT is efficient in consideration of energy efficiency, a current needs to flow in the lamination direction of the magnetoresistance effect element when data is written. A write current may degrade the characteristics of a magnetoresistance effect element.

In addition, in recent years, as a method in which magnetization rotation is enabled without a current flowing in the lamination direction of a magnetoresistance effect element, a spin current magnetized rotation element using a spin orbital torque (SOT) according to a pure spin current generated by a spin orbit interaction has been focused upon (for example, Nature Nanotechnology (2016) (DOI: 10.1038/NNANO2016.29, S. Fukami, T. Anekawa, C. Zhang, and H. Ohno)).

An SOT is induced by a pure spin current that is generated by a spin orbit interaction or the Rashba effect at an interface between different materials. A current for inducing an SOT in a magnetoresistance effect element flows in a direction crossing the lamination direction of the magnetoresistance effect element. That is, there is no need for a current to flow in the lamination direction of the magnetoresistance effect element and a longer lifespan for the magnetoresistance effect element can be expected.

It has been reported in Nature Nanotechnology (2016) (DOI: 10.1038/NNANO2016.29, S. Fukami, T. Anekawa, C. Zhang, and H. Ohno) that an inversion current density due to an SOT is substantially the same as an inversion current density due to an STT. Therefore, an inversion current density in a current SOT method is insufficient for high integration of a magnetoresistance effect element and realizing low energy consumption. In order to further reduce an inversion current density, it is necessary to use a material that causes a strong spin Hall effect.

In addition, as a material for a spin-orbit torque wiring, heavy metal materials such as Ta used in Nature Nanotechnology (2016) (DOI: 10.1038/NNANO2016.29, S. Fukami, T. Anekawa, C. Zhang, and H. Ohno) may be exemplified. Since such materials have high resistivity, when a thin film wiring made of such a material is used, there is a problem of power consumption increasing.

### SUMMARY OF THE INVENTION

The present disclosure has been made in view of the above problems, and an object of the present disclosure is to provide a spin current magnetized rotation element, a magnetoresistance effect element and a magnetic memory that reduce an inversion current density by generating a strong spin Hall effect.

The inventors found that, when a spin-orbit torque wiring including a superparamagnetic body is used, a strong spin Hall effect is caused, and magnetization rotation of a ferromagnetic layer can be easily performed, that is, even if a current density of an inversion current that flows in a spin-orbit torque wiring layer is reduced, magnetization rotation can be performed with an efficiency that is equal to or higher than that of a spin current magnetized rotation element of the related art. That is, in order to solve the above problem, the present disclosure provides the following aspects.

(1) A spin current magnetized rotation element including: a first ferromagnetic layer configured for a magnetization direction to be changed; and a spin-orbit torque wiring layer, wherein a first direction is defined as a direction orthogonal to a plane of the first ferromagnetic layer, and the spin-orbit torque wiring layer extends in a second direction intersecting the first direction and is positioned in the first direction from the first ferromagnetic layer, and wherein the spin-orbit torque wiring layer includes a superparamagnetic body therein, and the superparamagnetic body contains any one of a magnetic element selected from a group consisting of Fe, Co, Ni, and Gd.

(2) In the spin current magnetized rotation element according to the first aspect, the superparamagnetic body may be dispersedly disposed in the spin-orbit torque wiring layer.

(3) In the spin current magnetized rotation element according to the first aspect, the superparamagnetic body may be disposed so that a superparamagnetic portion in an island shape is formed in the spin-orbit torque wiring layer.

(4) In the spin current magnetized rotation element according to the first aspect, the superparamagnetic body may be disposed so that a superparamagnetic portion in a layer shape is formed, and the superparamagnetic portion may disposed at one position between a first surface of the spin-orbit torque wiring layer on a side of the first ferromagnetic layer and a second surface of the spin-orbit torque wiring layer on a side opposite to the first surface in a direction orthogonal to the plane of the spin-orbit torque wiring layer.

(5) In the spin current magnetized rotation element according to the first aspect, two portions of the spin-orbit torque wiring layer disposed with the superparamagnetic portion in a layer shape therebetween may contain materials that are different from each other.

(6) In the spin current magnetized rotation element according to the first aspect, the spin-orbit torque wiring layer may contain a heavy metal element having an atomic number that is equal to or higher than an atomic number of yttrium.

(7) In the spin current magnetized rotation element according to the first aspect, the superparamagnetic body may have a particle size of 10 nm or less.

(8) In the spin current magnetized rotation element according to the first aspect, the superparamagnetic body may contain an oxide of any one of a magnetic element selected from a group consisting of Fe, Co, Ni, and Gd.

(9) A magnetoresistance effect element according to a second aspect includes: the spin current magnetized rotation element according to the first aspect; a second ferromagnetic layer configured for a magnetization direction to be fixed; and a non-magnetic layer that is interposed between the first ferromagnetic layer and the second ferromagnetic layer.

(10) A magnetic memory according to a third aspect includes the plurality of magnetoresistance effect elements according to the second aspect.

According to the spin current magnetized rotation element of the above aspect, even if a current density of an inversion current that flows in the spin-orbit torque wiring layer is reduced, magnetization rotation can be performed with an efficiency that is equal to or higher than that of a spin current magnetized rotation element of the related art.

### BRIEF DESCRIPTION OF THE DRAWINGS

FIG. 1 is a perspective view schematically showing a spin current magnetized rotation element according to a first embodiment of the present disclosure.

FIG. 2 is a perspective view schematically showing a spin current magnetized rotation element according to a second embodiment of the present disclosure.

FIG. 3 is a perspective view schematically showing a spin current magnetized rotation element according to a third embodiment of the present disclosure.

FIG. 4 is a cross-sectional view schematically showing a method of producing the spin current magnetized rotation element according to the first embodiment.

FIG. 5 is a cross-sectional view schematically showing a method of producing the spin current magnetized rotation element according to the first embodiment.

FIG. 6 is a cross-sectional view schematically showing a method of producing the spin current magnetized rotation element according to the second embodiment.

FIG. 7 is a cross-sectional view schematically showing a method of producing the spin current magnetized rotation element according to the second embodiment.

FIG. 8 is a cross-sectional view schematically showing a method of producing the spin current magnetized rotation element according to the third embodiment.

FIG. 9 is a cross-sectional view schematically showing a method of producing the spin current magnetized rotation element according to the third embodiment.

FIG. 10 is a perspective view schematically showing a magnetoresistance effect element according to the present disclosure.

FIG. 11 is a plan view of a magnetic memory according to the present disclosure.

### DETAILED DESCRIPTION OF THE INVENTION

The present embodiment will be appropriately described below in detail with reference to the drawings. In the drawings used in the following description, in order to facilitate understanding of features of the present disclosure, characteristic parts are enlarged for convenience of illustration in some cases, and the dimensional proportions of components may be different from actual components. Materials, sizes, and the like exemplified in the following description are examples not liming the present disclosure, and can be appropriately changed within a range in which effects of the present disclosure are obtained.

### Spin Current Magnetized Rotation Element According to First Embodiment

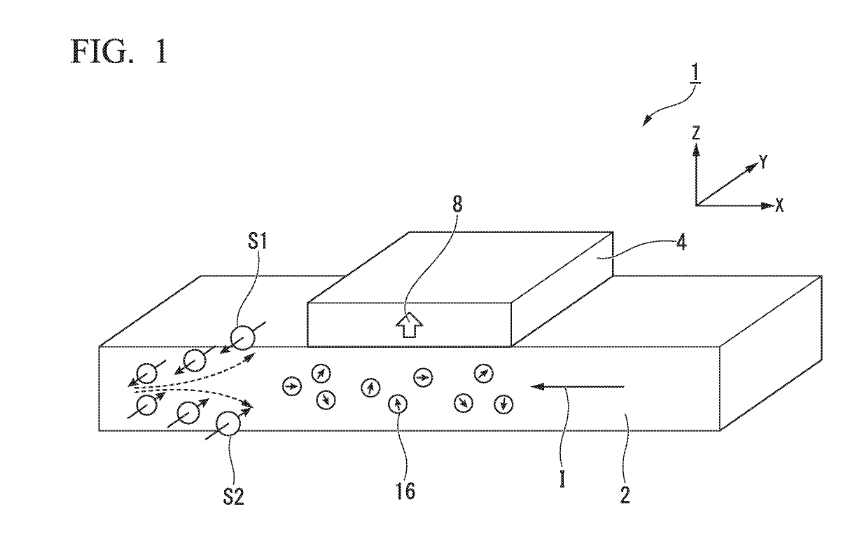

FIG. 1 is a perspective view schematically showing a spin current magnetized rotation element 1 according to a first embodiment of the present disclosure. The spin current magnetized rotation element 1 includes a first ferromagnetic layer 4 and a spin-orbit torque wiring layer 2 that extends in an X direction crossing a Z direction which is a direction orthogonal to the plane of the first ferromagnetic layer 4 and is positioned in a −Z direction from the first ferromagnetic layer 4.

### <Spin-Orbit Torque Wiring Layer>

In FIG. 1, the spin-orbit torque wiring layer 2 is bonded to the first ferromagnetic layer 4. The spin-orbit torque wiring layer 2 may be directly connected to the first ferromagnetic layer 4 or may be connected to the first ferromagnetic layer 4 with another layer therebetween.

It is preferable that a layer interposed between the spin-orbit torque wiring layer 2 and the first ferromagnetic layer 4 not dissipate the spin propagated from the spin-orbit torque wiring layer 2. For example, it is known that silver, copper, magnesium, aluminum and the like have a long spin diffusion length of 100 nm or more and are unlikely to dissipate the spin.

In addition, the thickness of the layer is preferably equal to or smaller than a spin diffusion length of a substance forming the layer.

When the thickness of the layer is equal to or smaller than the spin diffusion length, the spin propagated from the spin-orbit torque wiring layer 2 can be sufficiently transmitted to the first ferromagnetic layer 4.

The spin-orbit torque wiring layer 2 is made of a material in which a spin current is generated due to a spin Hall effect when a current flows. As such a material, a material having a configuration in which a spin current is generated in the spin-orbit torque wiring layer 2 is sufficient. Therefore, the material is not limited to a material including a single element, and it may include a part made of a material in which a spin current is generated and a part made of a material in which no spin current is generated.

A phenomenon in which, when a current flows in a wiring, a first spin S1 and a second spin S2 are bent in opposite directions orthogonal to the direction of the current based on a spin orbit interaction, and a spin current is induced is called a spin Hall effect. The general Hall effect and the spin Hall effect are the same in that mobile (moving) charges (electrons) are bent in the direction of motion (movement). However, the general Hall effect and the spin Hall effect are greatly different in that charged particles that move in a magnetic field receive a Lorentz force and are bent in a movement direction in the general Hall effect, but a movement direction is bent only by movement of electrons (only when a current flows) even though there is no magnetic field in the spin Hall effect.

Since the number of electrons with the first spin S1 and the number of electrons with the second spin S2 are the same in a non-magnetic material (material that is not a ferromagnetic material), the number of electrons with the first spin Si that are directed in a direction of a surface in which the first ferromagnetic layer 4 is disposed on the spin-orbit torque wiring layer 2 in the drawing is the same as the number of electrons with the second spin S2 that are directed in a direction opposite to a flow of electrons of the first spin S1. Therefore, a current of a net flow of charges becomes zero. A spin current that occurs without this current is specifically called a pure spin current.

Here, when a flow of electrons of the first spin S1 is denoted as J↑, a flow of electrons of the second spin S2 is denoted as J↓ and a spin current is denoted as JS, JS=J↑−J↓ is defined. In FIG. 1, JS as a pure spin current flows upward in the drawing. Here, JS is a flow of electrons with a polarizability of 100%.

The spin-orbit torque wiring layer 2 may contain a non-magnetic heavy metal. Here, a heavy metal refers to a metal having a specific gravity that is equal to or higher than that of yttrium.

In this case, the non-magnetic heavy metal is preferably a non-magnetic metal including d electrons or f electrons in the outermost shell and having an atomic number that is equal to or larger than 39, that is, a larger atomic number that is equal to or larger than that of yttrium. This is because such a non-magnetic metal has a strong spin orbit interaction causing the spin Hall effect.

In general, when a current flows in a metal, all the electrons move a direction opposite to the current irrespective of the direction of the spin. However, since a non-magnetic metal including d electrons or f electrons in the outermost shell and having a large atomic number has a strong spin orbit interaction, a direction of movement of electrons depends on a direction of the spin of electrons due to the spin Hall effect, and a pure spin current JS is likely to be generated.

In addition, the spin-orbit torque wiring layer 2 may contain a topological insulator. A topological insulator is a substance which includes an insulator or a high resistance component therein and has a surface in a spin-polarized metal state. There is an internal magnetic field called a spin orbit interaction in the substance. Thus, even if there is no external magnetic field, a new topological phase is exhibited due to an effect of the spin orbit interaction. This is a topological insulator, and a pure spin current can be generated with high efficiency due to a strong spin orbit interaction and breaking of inversion symmetry at the edge.

As the topological insulator, for example, SnTe, Bi_{1.5}Sb_{0.5}Te_{1.7}Se_{1.3}, T1BiSe₂, Bi₂Te₃, (Bi₁₋ₓSbₓ)₂Te₃, and the like are preferable. Such topological insulators can generate a spin current with high efficiency.

In addition, the spin-orbit torque wiring layer 2 according to the present embodiment includes a superparamagnetic body 16 therein. In this specification, the superparamagnetic body refers to fine particles exhibiting superparamagnetism. Superparamagnetism refers to an effect in which a direction of spontaneous magnetization thermally fluctuates due to a thermal disturbance in very small ferromagnetic material fine particles, and the apparent magnetization of the fine particles becomes 0. In the superparamagnetic body, the energy with which individual spins vibrate due to thermal disturbance is larger than the energy (magnetic anisotropy energy) with which spins of adjacent ferromagnetism atoms are aligned in the same direction. Individual spins maintain a magnetic moment with the same magnitude as in a ferromagnetic state, but the apparent magnetization of the superparamagnetic body is vectorially cancelled out and becomes 0. When a magnetic anisotropy energy per unit volume is denoted as K (anisotropic constant), the magnetic anisotropy energy of fine particles of the volume V is represented as KV. When an energy kbT (here, kb represents the Boltzmann constant) of thermal vibration at the absolute temperature T is larger than the potential, that is, when kbT>KV is satisfied, fine particles become a superparamagnetic body. Therefore, when a volume of fine particles made of the ferromagnetic material decreases, it is possible to create a superparamagnetic state. In general, when the particle size of fine particles is 10 nm or less, a state becomes a superparamagnetic state. When fine particles are not spherical, the particle size refers to a diameter of a circumscribing sphere that circumscribes the particles.

When the spin-orbit torque wiring layer 2 contains the superparamagnetic body 16 therein, conductive spins are spin-scattered by the superparamagnetic body 16, and the symmetry in the spin-orbit torque wiring layer 2 collapses. The collapse of the symmetry creates an internal field in the spin-orbit torque wiring layer 2 and a pure spin current is generated with high efficiency. In addition, the superparamagnetic body maintains very little spin information, and can generate a spin current by creating a paramagnetic state in which a spin state continues.

The superparamagnetic body 16 is fine particles including a magnetic element exhibiting ferromagnetism such as Fe, Co, Ni, and Gd. The superparamagnetic body 16 may contain oxides of magnetic elements exhibiting ferromagnetism such as Fe, Co, Ni, and Gd. Such oxides include, for example, FeOₓ, CoFeOₓ, and NiOₓ. As shown in FIG. 1, the superparamagnetic body 16 is dispersed and disposed in the spin-orbit torque wiring layer 2. The particle size of the superparamagnetic body 16 is preferably 10 nm or less as described above so that superparamagnetism is exhibited.

### <First Ferromagnetic Layer>

The first ferromagnetic layer 4 is laminated and disposed on the spin-orbit torque wiring layer 2 in a +Z direction crossing the X direction. The first ferromagnetic layer 4 has a magnetization 8 whose magnetization direction can be changed. While the magnetization 8 is parallel to the Z direction in FIG. 1, it may be parallel to the X direction or may be parallel to the Y direction crossing both the X direction and the Z direction. In addition, the magnetization 8 may be inclined with respect to any or all of the X direction, the Y direction, and the Z direction.

A ferromagnetic material can be used for the first ferromagnetic layer 4. For the first ferromagnetic layer 4, for example, a metal selected from the group consisting of Cr, Mn, Co, Fe and Ni, an alloy containing at least one of these metals, and an alloy containing such a metal and at least one element of B, C, and N may be used. Specifically, Co—Fe, Co—Fe—B, and Ni—Fe can be exemplified as a material for the first ferromagnetic layer 4. In addition, Heusler alloys such as Co₂FeSi, Co₂FeGe, Co₂FeGa, Co₂MnSi, Co₂Mn₁₋ₐFeₐAl_{b}Si_{1-b}, and Co₂FeGe_{1-c}Ga_{c} can be used.

### <Principle of Spin Orbital Torque Type Magnetized Rotation Element>

Next, the principle of the spin current magnetized rotation element 1 will be described with reference to FIG. 1.

As shown in FIG. 1, when an inversion current 1 is applied to the spin-orbit torque wiring layer 2, the first spin S1 and the second spin S2 are bent due to the spin Hall effect. As a result, the pure spin current JS is generated in the Z direction. Since the first spin S1 and the second spin S2 are scattered by the superparamagnetic body 16 disposed in the spin-orbit torque wiring layer 2, the pure spin current JS is generated with high efficiency.

In FIG. 1, since the first ferromagnetic layer 4 is laminated and disposed on the spin-orbit torque wiring layer 2 in the +Z direction therefrom, the pure spin current JS diffuses and flows into the first ferromagnetic layer 4. That is, the spins are injected to the first ferromagnetic layer 4. The injected spins impart a spin orbital torque (SOT) to the magnetization 8 of the first ferromagnetic layer 4 and generate magnetization rotation. In FIG. 1, the magnetization 8 of the first ferromagnetic layer 4 is schematically shown as one magnetization that is positioned at the center of gravity of the first ferromagnetic layer 4.

Therefore, in the spin current magnetized rotation element shown in FIG. 1, since the pure spin current JS is generated by the superparamagnetic body 16 with high efficiency, even if a current density of the inversion current I is reduced, magnetization rotation can be performed with an efficiency that is equal to or higher than that of a spin current magnetized rotation element of the related art.

### Spin Current Magnetized Rotation Element According to Second Embodiment

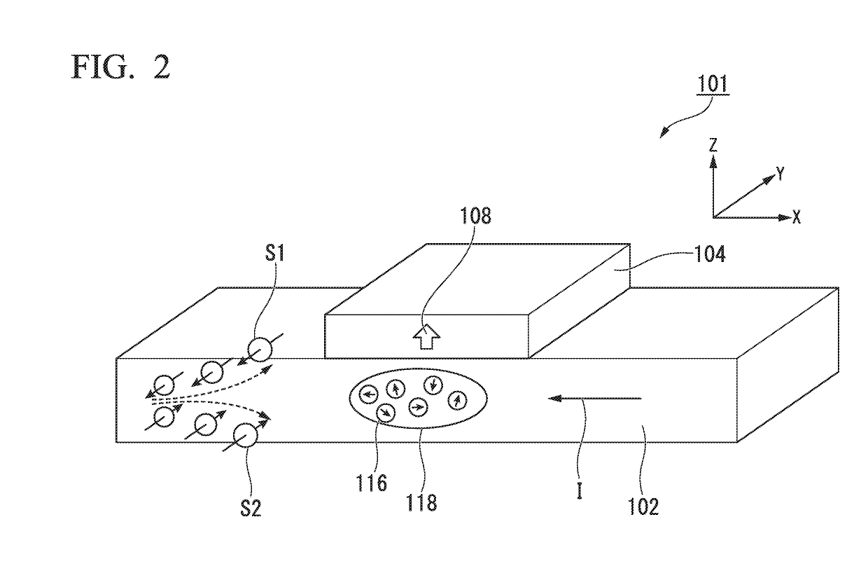

FIG. 2 is a perspective view schematically showing a spin current magnetized rotation element 101 according to a second embodiment of the present disclosure. The spin current magnetized rotation element 101 includes a first ferromagnetic layer 104 and a spin-orbit torque wiring layer 102 that extends in the X direction crossing the Z direction which is a direction orthogonal to the plane of the first ferromagnetic layer 104 and is positioned in the −Z direction from the first ferromagnetic layer 104. The first ferromagnetic layer 104 has a magnetization 108 whose magnetization direction can be changed.

The spin current magnetized rotation element 101 shown in FIG. 2 is different from the spin current magnetized rotation element 1 shown in FIG. 1 in that a superparamagnetic body 116 is disposed so that a superparamagnetic portion 118 in an island shape is formed in the spin-orbit torque wiring layer 102. Since the configuration is otherwise the same as that of the spin current magnetized rotation element 1, detailed description thereof will be omitted.

While the spin-orbit torque wiring layer 102 that includes only one superparamagnetic portion 118 in an island shape is shown in FIG. 2, the spin-orbit torque wiring layer 102 may include a plurality of superparamagnetic portions 118.

Since the superparamagnetic portion 118 of the spin current magnetized rotation element 101 is in an island shape, spins that flow into the spin-orbit torque wiring layer 102 are locally strongly scattered by the superparamagnetic body 116 localized in the superparamagnetic portion 118. Therefore, even if the pure spin current JS is generated with high efficiency and a current density of the inversion current I is reduced, magnetization rotation can be performed with an efficiency that is equal to or higher than that of a spin current magnetized rotation element of the related art. In addition, the superparamagnetic portion 118 can be formed in an area in the vicinity of the first ferromagnetic layer 104. Therefore, the pure spin current JS can be generated in the vicinity of the first ferromagnetic layer 104, and magnetization rotation can be performed with high efficiency.

### Spin Current Magnetized Rotation Element According to Third Embodiment

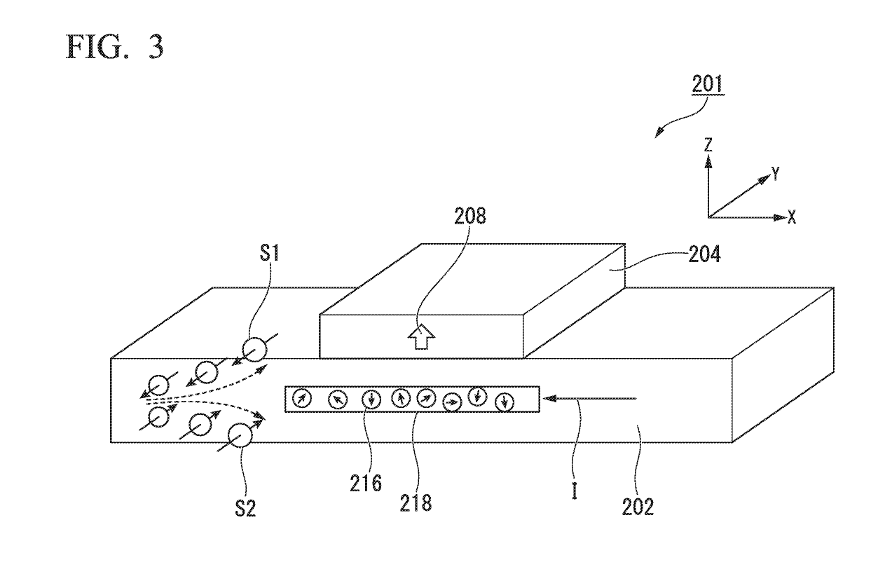

FIG. 3 is a perspective view schematically showing a spin current magnetized rotation element 201 according to a third embodiment of the present disclosure. The spin current magnetized rotation element 201 includes a first ferromagnetic layer 204 and a spin-orbit torque wiring layer 202 that extends in the X direction crossing the Z direction which is a direction orthogonal to the plane of the first ferromagnetic layer 204 and is positioned in the −Z direction from the first ferromagnetic layer 204. The first ferromagnetic layer 204 has a magnetization 208 whose magnetization direction can be changed.

The spin current magnetized rotation element 208 shown in FIG. 3 is different from the spin current magnetized rotation element 1 shown in FIG. 1 and the spin current magnetized rotation element 101 shown in FIG. 2 in that a superparamagnetic body 216 is disposed so that a superparamagnetic portion 218 in a layer shape is formed in the spin-orbit torque wiring layer 202. Since the configuration is otherwise the same as those of the spin current magnetized rotation elements 1 and 101, detailed description thereof will be omitted.

The superparamagnetic portion 218 in a layer shape may be disposed at any position between a first surface of the spin-orbit torque wiring layer 202 positioned on the side of the first ferromagnetic layer 204 and a second surface on the side opposite to the first surface in the direction orthogonal to the plane of the spin-orbit torque wiring layer 202. Spins that flow into the spin-orbit torque wiring layer 202 are locally strongly scattered by the superparamagnetic body 216 localized in the superparamagnetic portion 218. Therefore, even if the pure spin current JS is generated with high efficiency and a current density of the inversion current I is reduced, magnetization rotation can be performed with an efficiency that is equal to or higher than that of a spin current magnetized rotation element of the related art. In addition, the superparamagnetic portion 218 can be formed in an area in the vicinity of the first ferromagnetic layer 204. Therefore, the pure spin current JS can be generated in the vicinity of the first ferromagnetic layer 204, and magnetization rotation can be performed with high efficiency.

In addition, two portions of the spin-orbit torque wiring layer 202 disposed with the superparamagnetic portion 218 with a structure in a layer shape therebetween may contain materials that are different from each other. In this case, spins that flow into the spin-orbit torque wiring layer 202 receive an influence of an internal field generated due to the asymmetry of the spin-orbit torque wiring layer 202 in the thickness direction. Therefore, even if the pure spin current JS is generated with high efficiency and a current density of the inversion current I is reduced, magnetization rotation can be performed with an efficiency that is equal to or higher than that of a spin current magnetized rotation element of the related art

### Method of Producing a Spin Current Magnetized Rotation Element According to First Embodiment

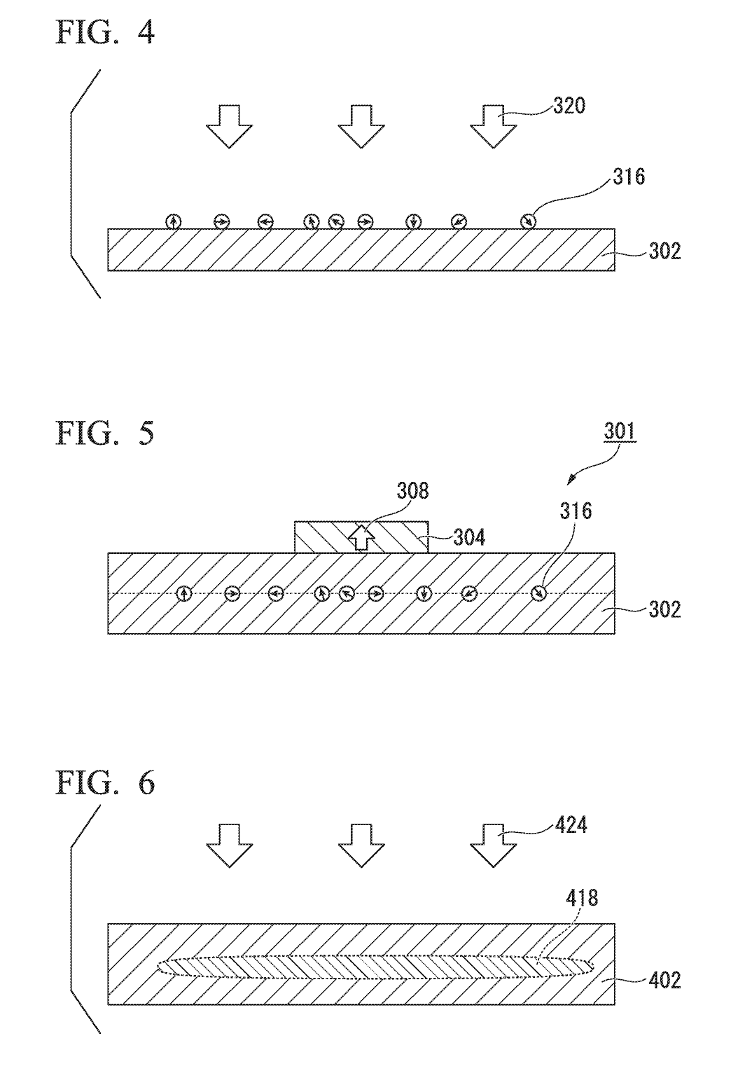

FIGS. 4 and 5 show cross-sectional views schematically showing a method of producing the spin current magnetized rotation element according to the first embodiment.

First, as shown in FIG. 4, a spin-orbit torque wiring layer 302 is formed on a substrate serving as a support. The spin-orbit torque wiring layer 302 can be formed using a known film forming method such as sputtering.

Next, a ferromagnetic material 320 which forms a superparamagnetic body is formed into a film using a known film forming method such as sputtering. The ferromagnetic material 320 is selected from among elements including Fe, Co, Ni, and Gd. When the ferromagnetic material 320 is formed into a film, if a low deposition rate is used, the ferromagnetic material 320 formed into a film aggregates on a surface of the spin-orbit torque wiring layer 302 and fine particles are formed. The deposition rate is adjusted so that the particle size of the fine particles becomes 10 nm or less, and thus a superparamagnetic body 316 can be formed. For example, when Fe is used as the ferromagnetic material 320, fine particles with a particle size of 10 nm or less can be formed by setting about 0.1 Å/second or less.

In addition, even if the substrate is heated without removing it from a deposition chamber while the ferromagnetic material 320 is formed into a film or after formation of the ferromagnetic material 320 into a film is completed, it is possible to promote aggregation of the ferromagnetic material 320 on a surface of the spin-orbit torque wiring layer 302. For example, when Fe is used as the ferromagnetic material 320, if the substrate is heated to 100° C. or higher and 300° C. or lower, fine particles with a particle size of 10 nm or less can be formed.

In addition, a material having a higher surface energy than a material contained in the spin-orbit torque wiring layer 302 can be used as the ferromagnetic material 320. In this case, the ferromagnetic material 320 aggregates due to surface energy and can form fine particles. For example, when W is used as a material of the spin-orbit torque wiring layer 302 and Co is used as a material of the ferromagnetic material 320, fine particles with a particle size of 10 nm or less can be formed.

As shown in FIG. 5, after the superparamagnetic body 316 is formed, the spin-orbit torque wiring layer 302 is additionally formed into a film using a known film forming method such as sputtering. A material used for forming a film of the spin-orbit torque wiring layer 302 after the superparamagnetic body 316 is formed can be the same material used for forming a film of the spin-orbit torque wiring layer 302 before the superparamagnetic body 316 is formed, but a different material can be selected. Next, a first ferromagnetic layer 304 is laminated on the spin-orbit torque wiring layer 302 and formed into a film using a known film forming method such as sputtering and thereby a spin current magnetized rotation element 301 is obtained.

When the magnetization of the superparamagnetic body 316 is measured, it can be confirmed that the superparamagnetic body 316 is formed. Even if the ferromagnetic material 320 is formed into a film, if no magnetization is measured on a film formation surface, it can be determined that the superparamagnetic body 316 is formed. In addition, since it is known that, when the particle size of fine particles made of a ferromagnetic material is 10 nm or less, the material behaves as a superparamagnetic body, when it is observed that fine particles with a particle size of 10 nm or less are formed using a transmission electron microscope (TEM), it can be confirmed that the superparamagnetic body 316 is formed.

### Method of Producing Spin Current Magnetized Rotation Element According to Second Embodiment

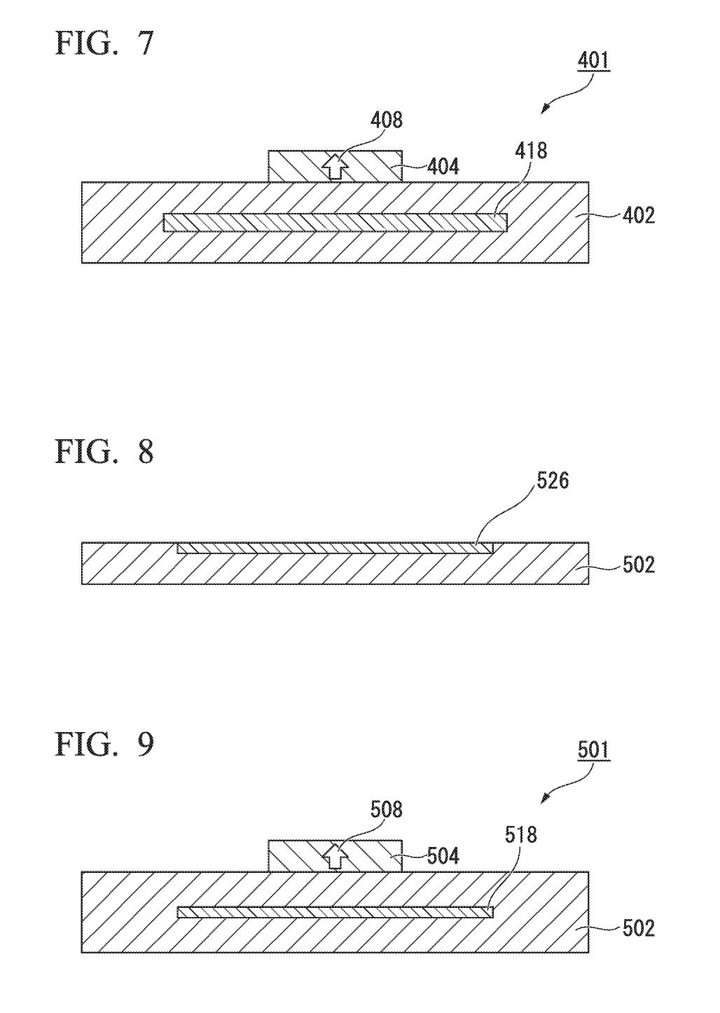

FIGS. 6 and 7 show cross-sectional views schematically showing a method of producing the spin current magnetized rotation element according to the second embodiment.

First, as shown in FIG. 6, a spin-orbit torque wiring layer 402 is formed on a substrate serving as a support using a ferromagnetic material. The spin-orbit torque wiring layer 402 can be formed using a known film forming method such as sputtering.

Next, a non-magnetic element 424 is sputtered with a high film forming energy. As the non-magnetic element 424, for example, Ta can be selected. As a film forming energy, for example, 10 to 50 eV can be selected. The non-magnetic element 424 is driven to a predetermined depth region in the spin-orbit torque wiring layer 402 according to the film forming energy. As a result, a so-called mixed layer or a region called a dead layer is formed. In this region, a ferromagnetic material constituting the spin-orbit torque wiring layer 402 is divided by the non-magnetic element 424, an effective volume of the ferromagnetic material is reduced, and a structure of fine particles made of a ferromagnetic material and with a particle size of 10 nm or less, that is, a superparamagnetic body is formed. Accordingly, as shown in FIG. 6, a superparamagnetic portion 418 in a layer shape containing a superparamagnetic body is formed in a predetermined region in the spin-orbit torque wiring layer 402. Here, when a depth to which the non-magnetic element 424 is driven and a region in the planar direction are adjusted, the superparamagnetic portion 418 can be made into a portion in an island shape.

Next, as shown in FIG. 7, a first ferromagnetic layer 404 is laminated on the spin-orbit torque wiring layer 402 and formed into a film using a known film forming method such as sputtering and thereby a spin current magnetized rotation element 401 is obtained. In addition, in FIG. 7, the superparamagnetic portion 418 is disposed at a predetermined depth in the spin-orbit torque wiring layer 402. However, the depth of the superparamagnetic portion 418 may be zero. That is, the superparamagnetic portion 418 may be disposed at an interface between the spin-orbit torque wiring layer 402 and the first ferromagnetic layer.

### Method of Producing Spin Current Magnetized Rotation Element According to Third Embodiment

FIGS. 8 and 9 are cross-sectional views schematically showing a method of producing the spin current magnetized rotation element according to the third embodiment.

First, as shown in FIG. 8, a spin-orbit torque wiring layer 502 made of a ferromagnetic material is formed on a substrate serving as a support. The spin-orbit torque wiring layer 502 can be formed using a known film forming method such as sputtering. Next, in a partial portion or the entire portion of the spin-orbit torque wiring layer 502, the surface is oxidized. An oxidized region 526 has, for example, a depth of 10 nm or less. Since the oxidized region 526 is very thin, a ferromagnetic material constituting the spin-orbit torque wiring layer 502 is divided by an oxide (for example, FeOx, CoFeOx, and NiOx), and a structure of fine particles with a particle size of 10 nm or less is formed. The structure of fine particles behaves as a superparamagnetic body.

Next, as shown in FIG. 9, the spin-orbit torque wiring layer 502 is additionally formed into a film using a known film forming method such as sputtering. Accordingly, a superparamagnetic portion 518 in a layer shape containing a superparamagnetic body is formed in the spin-orbit torque wiring layer. A material used for forming a film of the spin-orbit torque wiring layer 502 after the oxidized region 526 is formed can be the same material used for forming a film of the spin-orbit torque wiring layer 502 after the oxidized region 526 is formed, but a different material can be selected. Next, a first ferromagnetic layer 504 is laminated into a film on the spin-orbit torque wiring layer 502 using a known film forming method such as sputtering and thereby a spin current magnetized rotation element 501 is obtained. Here, formation of the spin-orbit torque wiring layer 502 into a film after the oxidized region 526 is formed can be omitted. In this case, the oxidized region 526, that is, the superparamagnetic portion 518, is disposed at an interface between the spin-orbit torque wiring layer 502 and the first ferromagnetic layer 504.

### (Magnetoresistance Effect Element)

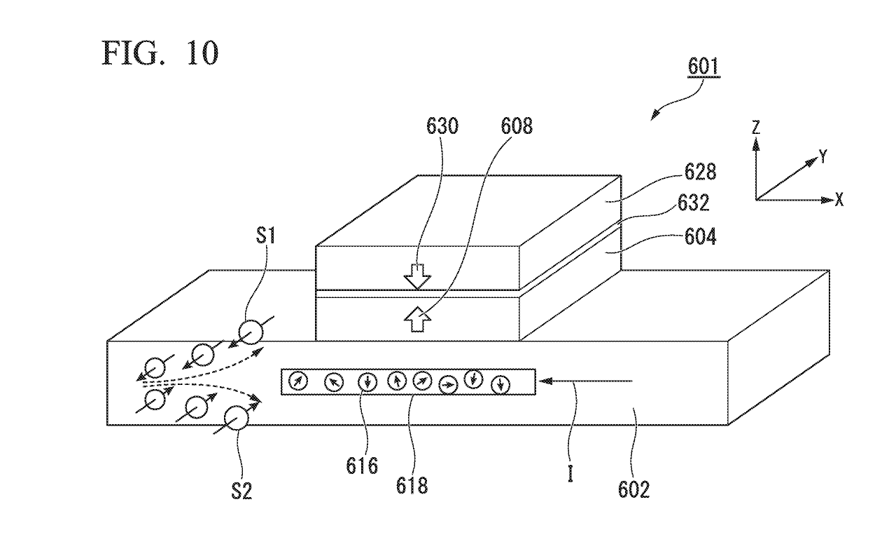

FIG. 10 is a perspective view schematically showing a magnetoresistance effect element 601 according to the present disclosure.

The magnetoresistance effect element 601 includes a spin current magnetized rotation element that includes a first ferromagnetic layer 604 and a spin-orbit torque wiring layer 602 that extends in the X direction crossing the Z direction which is a direction orthogonal to the plane of the first ferromagnetic layer 604 and is bonded to the first ferromagnetic layer 4, a second ferromagnetic layer 628, and a non-magnetic layer 632 interposed between the first ferromagnetic layer 604 and the second ferromagnetic layer 628.

The spin-orbit torque wiring layer 602 includes a superparamagnetic body 616 therein. In the example shown in FIG. 10, the superparamagnetic body 616 is disposed so that a superparamagnetic portion 618 in a layer shape is formed. However, for example, as shown in FIG. 1, the superparamagnetic body 616 may be dispersed and disposed in the spin-orbit torque wiring layer 602. In addition, as shown in FIG. 2, the superparamagnetic body 616 may be disposed so that the superparamagnetic portion 618 in an island shape is formed in the spin-orbit torque wiring layer 602. Since the configuration and effects of the superparamagnetic body 616 and the superparamagnetic portion 618 are the same as the configuration and effects described in the spin current magnetized rotation elements 1, 101, and 201 shown in FIGS. 1 to 3, detailed description thereof will be omitted.

The first ferromagnetic layer 604 has a magnetization 608 whose magnetization direction can be changed. In addition, the second ferromagnetic layer has a magnetization 630 whose direction is fixed.

### <Second Ferromagnetic Layer>

The magnetoresistance effect element 601 functions when the magnetization 630 of the second ferromagnetic layer 628 is fixed in one direction, and a direction of the magnetization 608 of the first ferromagnetic layer 604 relatively changes. In application to an MRAM of a retention force differential type (pseudo spin valve type), a retention force of the second ferromagnetic layer 628 is assumed to be larger than a retention force of the first ferromagnetic layer 604. In application to an MRAM of an exchange bias type (spin valve type), a magnetization direction of the second ferromagnetic layer 628 is fixed by exchange coupling with a semi-ferromagnetic layer.

In addition, when the non-magnetic layer 632 is made of an insulator, the magnetoresistance effect element 601 is a tunneling magnetoresistance (TMR) element. When the non-magnetic layer 632 is made of a metal, the magnetoresistance effect element 601 is a giant magnetoresistance (GMR) element.

As a lamination structure of the magnetoresistance effect element 601, a known lamination structure of the magnetoresistance effect element can be used. For example, each layer may be made of a plurality of layers, and may include another layer such as an antiferromagnetic layer for fixing a magnetization direction of the second ferromagnetic layer 628. The second ferromagnetic layer 628 is called a fixed layer or a reference layer, and the first ferromagnetic layer 604 is called a free layer or a recording layer.

A known material can be used as a material of the second ferromagnetic layer 628 and the same material as that of a first ferromagnetic layer 628 can be used. In the example shown in FIG. 10, since the first ferromagnetic layer 604 has magnetization in the direction orthogonal to the plane, it is desirable that the second ferromagnetic layer 628 also have magnetization in the direction orthogonal to the plane. When the first ferromagnetic layer 604 has magnetization in an in-plane direction, it is desirable that the second ferromagnetic layer 628 also have magnetization in the in-plane direction.

In addition, in order to set a coercive force of the second ferromagnetic layer 628 with respect to the first ferromagnetic layer 604 to be larger, an antiferromagnetic material such as IrMn and PtMn may be used as a material in contact with the second ferromagnetic layer 628. In addition, in order to prevent a leakage magnetic field of the second ferromagnetic layer 628 from influencing the first ferromagnetic layer 604, a structure of synthetic ferromagnetic coupling may be used.

<Non-Magnetic layer>

A known material can be used for the non-magnetic layer 632. For example, when the non-magnetic layer 632 is made of an insulator (in the case of a tunnel barrier layer), Al₂O₃, SiO₂, MgO, and MgAl₂O₄ can be used as a material thereof. In addition to these materials, materials in which some of Al, Si, and Mg are replaced with Zn and Be can be used. Among them, since MgO and MgAl₂O₄ are materials that can realize coherent tunneling, spins can then be efficiently injected. In addition, when the non-magnetic layer 632 is made of a metal, Cu, Au, and Ag can be used as a material thereof. In addition, when the non-magnetic layer 632 is made of a semiconductor, Si, Ge, CuInSe₂, CuGaSe₂, and Cu(In, Ga)Se₂ can be used as a material thereof.

In addition, the magnetoresistance effect element 601 may include another layer. For example, an underlayer may be provided on a surface opposite to the non-magnetic layer 632 of the first ferromagnetic layer 604 or a cap layer may be provided on a surface opposite to the non-magnetic layer 632 of the second ferromagnetic layer 628.

### (Principle of Magnetoresistance Effect Element)

Next, the principle of the magnetoresistance effect element 601 will be described.

In FIG. 10, a direction of the magnetization 608 is antiparallel to a direction of the magnetization 630 (antiparallel state). In this case, the electrical resistance between the first ferromagnetic layer 604 and the second ferromagnetic layer 628 is in a high resistance state.

When an inversion current I flows in the spin-orbit torque wiring layer 602, the spin current JS is injected into the first ferromagnetic layer 604. At this time, the magnetization 608 of the first ferromagnetic layer 604 rotates and reverses, and a direction of the magnetization 608 is parallel to a direction of the magnetization 630 of the second ferromagnetic layer 628 (parallel state). In this case, the electrical resistance between the first ferromagnetic layer 604 and the second ferromagnetic layer 628 is in a high resistance state. Accordingly, depending on whether directions of the magnetization 608 and the magnetization 630 are in a parallel state or an antiparallel state, the magnetoresistance effect element 601 functions as a magnetic memory that keeps 0/1 data that corresponds to the state of the electrical resistance between the first ferromagnetic layer 604 and the second ferromagnetic layer 628.

### (Magnetic Memory)

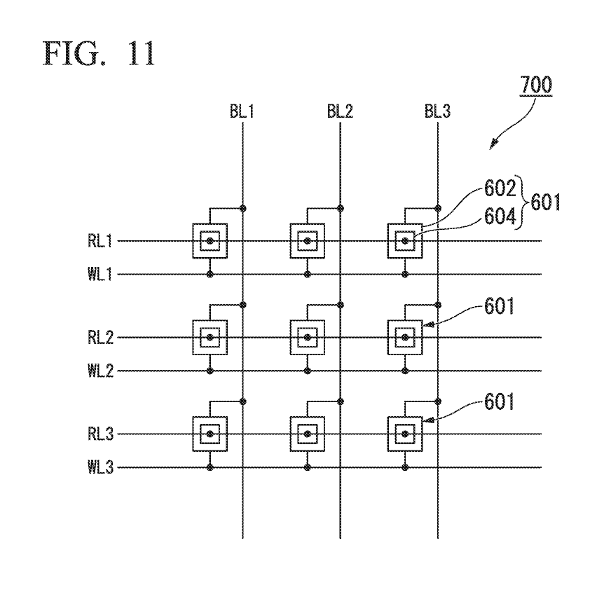

FIG. 11 is a plan view of a magnetic memory 700 according to the present disclosure. In the magnetic memory 700 shown in FIG. 11, the magnetoresistance effect elements 601 are arranged in a 3x3 matrix in an array form. FIG. 11 is an example of a magnetic memory, and the type of the magnetoresistance effect element 601, the number thereof and disposition thereof are arbitrary. In addition, a control unit may be provided for all of the magnetoresistance effect elements 601 or may be provided for each magnetoresistance effect element 601.

One of word lines WL1 to WL3, one of bit lines BL1 to BL3, and one of lead lines RL1 to RL3 are connected to the respective magnetoresistance effect elements 601.

When the word lines WL1 to WL3 and the bit lines BL1 to BL3 to which a current is applied are selected, a pulse current flows in the spin-orbit torque wiring 602 of an arbitrary magnetoresistance effect element 601, and a write operation is performed. In addition, when the lead lines RL1 to RL3 and the bit lines BL1 to BL3 to which a current is applied are selected, a current flows in the lamination direction of an arbitrary magnetoresistance effect element 601 and a read operation is performed. The word lines WL1 to WL3, the bit lines BL1 to BL3, and the lead lines RL1 to RL3 to which a current is applied can be selected by a transistor or the like.

While exemplary embodiments of the present disclosure have been described above in detail, the present disclosure is not limited to these specific embodiments, and various modifications and alternations can be made in a range within the spirit and scope of the present disclosure described in the scope of the claims.

### EXPLANATION OF REFERENCES

1, 101, 201: Spin current magnetized rotation element

2, 102, 202, 302, 402, 502, 602: Spin-orbit torque wiring layer

4, 104, 204, 304, 404, 504, 604: First ferromagnetic layer

8, 108, 208: Magnetization of first ferromagnetic layer

16, 116, 216, 316: Superparamagnetic body

118, 218, 418, 518: Superparamagnetic portion

320: Ferromagnetic material

424: Non-magnetic element

526: Oxidized region

628: Second ferromagnetic layer

630: Magnetization of second ferromagnetic layer

632: Non-magnetic layer

601: Magnetoresistance effect element

700: Magnetic memory

S1: First spin

S2: Second spin

I: Current

Js: Pure spin current

1. A spin current magnetized rotation element comprising:
a first ferromagnetic layer configured for a magnetization direction to be changed; and
a spin-orbit torque wiring layer,
wherein a first direction is defined as a direction orthogonal to a plane of the first ferromagnetic layer, and the spin-orbit torque wiring layer extends in a second direction intersecting the first direction and is positioned in the first direction from the first ferromagnetic layer, and
wherein the spin-orbit torque wiring layer includes a plurality of superparamagnetic bodies therein, and
each of the superparamagnetic bodies contains any one of a magnetic element selected from a group consisting of Fe, Co, Ni, and Gd.

2. The spin current magnetized rotation element according to claim 1,
wherein the superparamagnetic bodies are dispersedly disposed in the spin-orbit torque wiring layer.

3. The spin current magnetized rotation element according to claim 1,
wherein the superparamagnetic bodies are disposed so that a superparamagnetic portion in an island shape is formed in the spin-orbit torque wiring layer.

4. The spin current magnetized rotation element according to claim 1,
wherein the superparamagnetic bodies are disposed so that a superparamagnetic portion in a layer shape is formed, and
the superparamagnetic portion is disposed at one position between a first surface of the spin-orbit torque wiring layer on a side of the first ferromagnetic layer and a second surface of the spin-orbit torque wiring layer on a side opposite to the first surface in a direction orthogonal to the plane of the spin-orbit torque wiring layer.

5. The spin current magnetized rotation element according to claim 4,
wherein two portions of the spin-orbit torque wiring layer disposed with the superparamagnetic portion in a layer shape therebetween contain materials that are different from each other.

6. The spin current magnetized rotation element according to claim 1,
wherein the spin-orbit torque wiring layer contains a heavy metal element having an atomic number that is equal to or higher than an atomic number of yttrium.

7. The spin current magnetized rotation element according to claim 1,
wherein the superparamagnetic bodies have a particle size of 10 nm or less.

8. The spin current magnetized rotation element according to claim 1,
wherein each of the superparamagnetic bodies contains an oxide of any one of a magnetic element selected from a group consisting of Fe, Co, Ni, and Gd.

9. A magnetoresistance effect element comprising:
the spin current magnetized rotation element according to claim 1;
a second ferromagnetic layer configured for a magnetization direction to be fixed; and
a non-magnetic layer that is interposed between the first ferromagnetic layer and the second ferromagnetic layer.

10. A magnetic memory comprising a plurality of magnetoresistance effect elements, each of which is the magnetoresistance effect element according to claim 9.

11. The spin current magnetized rotation element according to claim 2,
wherein the spin-orbit torque wiring layer contains a heavy metal element having an atomic number that is equal to or higher than an atomic number of yttrium.

12. The spin current magnetized rotation element according to claim 3,
wherein the spin-orbit torque wiring layer contains a heavy metal element having an atomic number that is equal to or higher than an atomic number of yttrium.

13. The spin current magnetized rotation element according to claim 4,
wherein the spin-orbit torque wiring layer contains a heavy metal element having an atomic number that is equal to or higher than an atomic number of yttrium.

14. The spin current magnetized rotation element according to claim 5,
wherein the spin-orbit torque wiring layer contains a heavy metal element having an atomic number that is equal to or higher than an atomic number of yttrium.

15. The spin current magnetized rotation element according to claim 2,
wherein the superparamagnetic bodies have a particle size of 10 nm or less.

16. The spin current magnetized rotation element according to claim 3,
wherein the superparamagnetic bodies have a particle size of 10 nm or less.

17. The spin current magnetized rotation element according to claim 4,
wherein the superparamagnetic bodies have a particle size of 10 nm or less.

18. The spin current magnetized rotation element according to claim 5,
wherein the superparamagnetic bodies have a particle size of 10 nm or less.

19. The spin current magnetized rotation element according to claim 6,
wherein the superparamagnetic bodies have a particle size of 10 nm or less.

20. The spin current magnetized rotation element according to claim 1, wherein the spin-orbit torque wiring layer contains a topological insulator.
